(19) United States
(12) Patent Application Publication
(10) Pub. No.: US 2012/0156866 A1
(43) Pub. Date: Jun. 21, 2012

(54) METHOD OF FORMING PATTERNS OF SEMICONDUCTOR DEVICE

(76) Inventor: Myung Kyu AHN, Gyeonggi-do (KR)

(21) Appl. No.: 13/326,048

(22) Filed: Dec. 14, 2011

(30) Foreign Application Priority Data
Dec. 15, 2010 (KR) 10-2010-0128297

(51) Int. Cl. H01L 21/336

(52) U.S. Cl. 438/585; 257/E21.409

(57) ABSTRACT

A method of forming patterns of a semiconductor device includes forming a hard mask layer over stack layers including first to third regions, forming first patterns on the hard mask layer of the first region and second and third patterns, including first auxiliary layers and spacers formed on both sides of the first auxiliary layer, on the hard mask layer of the second and the third regions, forming hard mask patterns by etching the hard mask layer exposed through the first to third patterns, and forming word lines in the first region, a dummy word line in the second region, and select lines in the third region by etching the stack layers exposed through the hard mask patterns.

### CROSS-REFERENCE TO RELATED APPLICATION

Priority to Korean patent application number 10-2010-0128297 filed on Dec. 15, 2010, the entire disclosure of which is incorporated by reference herein, is claimed.

### BACKGROUND

Exemplary embodiments relate to a method of forming the patterns of a semiconductor device and, more particularly, to a method of forming the patterns of a semiconductor device which is capable of reducing an error value of an interval between the gate lines.

Patterns forming a semiconductor device are formed in various sizes. For example, a NAND flash memory device includes a plurality of strings formed in the memory cell array region of the NAND flash memory device. Each of the strings includes a source select transistor, a drain select transistor, and a plurality of memory cells coupled in series between the source select transistor and the drain select transistor. The gate of the source select transistor is coupled to a source select line, the gate of the drain select transistor is coupled to a drain select line, and the gates of the memory cells are coupled to respective word lines. Furthermore, a dummy element may be formed between the drain select transistor and the memory cells and between the source select transistor and the memory cells in order to prevent the occurrence of a disturbance phenomenon. The dummy element is coupled to a dummy word line which is a passing word line. In general, the drain select line and the source select line of the string are formed to have a wider width than the word line, and the word line is formed to have a narrower width than the exposure resolution limit width in order to increase the degree of integration of the devices.

In order to form the word lines each having a line width narrower than the exposure resolution limit width as described above, spacer patterning technology (SPT) was proposed.

FIGS. 1A, 1B, and 2 are diagrams illustrating a method of forming the patterns of a semiconductor device employing conventional spacer patterning technology.

Referring to FIG. 1A, first, a plurality of first auxiliary patterns 1 spaced apart from each other with a trenches T interposed therebetween are formed. A spacer layer is formed on a surface of the first auxiliary patterns 1, and spacers 3 are formed on the sidewalls of the trenches T by etching the spacer layer using an etch-back process.

For example, in a NAND flash memory device, the spacers 3 may be formed in a memory cell region R1 where memory cells will be formed, a dummy region R2 where dummy elements will be formed, and a select transistor region R3 where drain select transistors or source select transistors will be formed. The dummy region R2 is disposed between the memory cell region R1 and the select transistor region R3. One of the first auxiliary patterns 1 is disposed at the boundary of the dummy region R2 and the select transistor region R3, and it includes one of the sidewalls disposed in the dummy region R2 and the other of the sidewalls disposed in the select transistor region R3. Furthermore, some of the first auxiliary patterns 1 are disposed in the memory cell region R1.

A width W1 of the spacer 3 formed on the sidewall of the first auxiliary pattern 1 disposed in the dummy region R2 defines the width of a dummy word line. Furthermore, a width W1 of the spacer 3 formed on the sidewall of the first auxiliary pattern 1 disposed in the memory cell region R1 defines the width of a word line. Furthermore, an interval L1 between the spacers 3 in the memory cell region R1 defines an interval between the word lines. An interval L2 between the spacers 3 at the boundary of the memory cell region R1 and the dummy region R2 defines an interval between the word line and the dummy word line and may be the same as the interval L1 between the spacers 3 in the memory cell region R1. A width L3 of the first auxiliary pattern 1 formed at the boundary of the select transistor region R3 and the dummy region R2 may be wider than the interval L1 between the spacers 3 in the memory cell region R1.

Meanwhile, the spacers 3 have the same width W1 due to the nature of the process. Accordingly, in order to form the drain select line or the source select line (hereinafter referred to as a ‘select line’) having a wider width than the word line, an additional pattern having a wider width than the width W1 of the spacer 3 is to be formed in the select transistor region R3.

Referring to FIG. 1B, the first auxiliary patterns 1 are removed, and a second auxiliary pattern 5 defining the width of the select line is formed in the select transistor region R3. The second auxiliary pattern 5 has a width W2 wider than the width W1 of the spacer 3.

In order to form the second auxiliary pattern 5, a photolithography process is to be further performed. To this end, an interval L4 between the second auxiliary pattern 5 and the spacer 3 is determined depending on the degree of the alignment of exposure masks which are used in the photolithography process. In general, when the exposure masks used to form the second auxiliary pattern 5 are aligned, there is an alignment error of ±20 nm. This makes it difficult to uniformly form the interval L4 between the second auxiliary pattern 5 and the spacer 3.

The patterns of the semiconductor device may be formed by using the spacer 3 and the second auxiliary pattern 5 formed through the above process. A method of forming the patterns of the semiconductor device by using the spacer 3 and the second auxiliary pattern 5 is described below with reference to FIG. 2.

FIG. 2 is a cross-sectional view showing part of a conventional semiconductor device. More particularly, FIG. 2 is a cross-sectional view showing the gate lines of a NAND flash memory device.

Referring to FIG. 2, the gate lines, including word lines WL, a dummy word line PWL, and a select line DSL/SSL, are patterned by using hard mask pattern HM as an etch mask. The word lines WL are formed in a memory cell region R1. The select line DSL/SSL may be a drain select line DSL or a source select line SSL formed in a select transistor region R3. The dummy word line PWL is formed in a dummy region R2 disposed between the memory cell region R1 and the select transistor region R3. The word lines WL, the dummy word line PWL, and the select line DSL/SSL may be formed by stacking a dielectric layer 27 and a second conductive layer 29 over a gate insulating layer 23 and a first conductive layer 25 which are stacked over the active region of a semiconductor substrate 21 and then patterning the second conductive layer 29 by using the hard mask pattern HM on the second conductive layer 29 as an etch mask. Furthermore, the exposed regions of the dielectric layer 27 and the first conductive layer 25 may be removed using an etch process by using the same hard mask pattern HM as an etch mask. Consequently, floating gates may be formed under the word lines WL and the dummy word line PWL. A first conductive layer pattern may be formed under the select line DSL/SSL and electrically coupled to the select line DSL/SSL through a contact hole formed in the dielectric layer 27.

The hard mask pattern HM used to pattern the word lines WL and the dummy word line PWL may have a line width W1 which is defined by the spacer and finer than the exposure resolution limit width. Furthermore, the hard mask pattern HM used to pattern the select line DSL/SSL may have a line width W2 which is defined by the second auxiliary pattern and wider than the hard mask pattern HM used to pattern the word line WL. An interval L1 between the word lines WL and an interval L1 between the word line WL and the dummy word line PWL may become uniform by controlling the deposition thickness of the spacer layer and the interval between the trenches as described above with reference to FIGS. 1A and 1B. On the other hand, an interval L4 between the select line DSL/SSL and the dummy word line WL which is defined by the alignment degree of exposure masks for forming a second auxiliary pattern is difficult to have a desired interval value owing to the misalignment of the exposure masks for forming the second auxiliary pattern. This makes it difficult to form the interval between the word line WL and the select line DSL/SSL without an error.

### BRIEF SUMMARY

Exemplary embodiments relate to a method of forming the patterns of a semiconductor device which is capable of reducing an error value of an interval between gate lines.

A method of forming patterns of a semiconductor device according to an aspect of the present disclosure includes forming a hard mask layer over stack layers including first to third regions, forming first patterns on the hard mask layer of the first region and second and third patterns, including first auxiliary layer and spacers formed on both sides of the first auxiliary layer, on the hard mask layer of the second and the third regions, forming hard mask patterns by etching the hard mask layer exposed through the first to third patterns, and forming word lines in the first region, a dummy word line in the second region, and select lines in the third region by etching the stack layers exposed through the hard mask patterns.

A method of forming patterns of a semiconductor device according to another aspect of the present disclosure includes forming a hard mask layer over stack layers including first to third regions; forming a first auxiliary layer over the hard mask layer and forming first to fourth trenches by etching the first auxiliary layer, wherein the first trenches are disposed in the first region, the second trench is disposed at a boundary of the first region and the second region, the third trench is disposed at a boundary of the second region and the third region, and the fourth trench is disposed in the third region; forming a second auxiliary layer along an entire surface including the first to fourth trenches and forming first spacers on sidewalls of the first trenches and on a sidewall of the second trench close to the first region by etching the second auxiliary layer in the first region; removing the first auxiliary layer in the first region and then forming second spacers on the other sidewall of the second trench close to the second region and on sidewalk of the third and the fourth trenches by etching the second auxiliary layer in the second and third regions; forming hard mask patterns by etching the hard mask layer exposed between the first and the second spacers and the remaining first auxiliary layer; and forming word lines in the first region, a dummy word line in the second region, and a select line in the third region by etching the stack layers exposed through the hard mask patterns.

A method of forming patterns of a semiconductor device according to yet another aspect of the present disclosure includes forming a hard mask layer over stack layers including first to third regions; forming a first auxiliary layer over the hard mask layer and forming first to fourth trenches by etching the first auxiliary layer, wherein the first trenches are disposed in the first region, the second trench is disposed at a boundary of the first region and the second region, the third trench is disposed at a boundary of the second region and the third region, and the fourth trench is disposed in the third region; forming a second auxiliary layer along an entire surface including the first to fourth trenches and forming a third auxiliary layer, covering the second and the third regions, on the second auxiliary layer; forming first spacers in the first region by etching the second auxiliary layer exposed through the third auxiliary layer, wherein a top surface of the first auxiliary layer between the first trenches is exposed; removing the exposed regions of the first auxiliary layer and then forming second spacers on sidewalls of the second to fourth trenches by etching the third auxiliary layer and the second auxiliary layer, wherein the first auxiliary layer between the first and the second trenches, between the second and the first trenches, and between the third and the fourth trenches is exposed and the hard mask layer is exposed through bottom surfaces of the second to fourth trenches; forming hard mask patterns by etching the hard mask layer exposed between the first and the second spacers and the remaining first auxiliary layer; and forming word lines in the first region, a dummy word line in the second region, and a select line in the third region by exposing the stack layers exposed through the hard mask patterns.

### BRIEF DESCRIPTION OF THE DRAWINGS

FIGS. 1A, 1B, and 2 are diagrams illustrating a method of forming the patterns of a semiconductor device employing conventional spacer patterning technology;

FIG. 3 is a cross-sectional view illustrating the patterns of a semiconductor device according to an embodiment of this disclosure;

FIGS. 4A to 8B are diagrams illustrating a method of forming the patterns of a semiconductor device according to a first embodiment of this disclosure; and

FIGS. 9A to 9G are cross-sectional views illustrating a method of forming the patterns of a semiconductor device according to a second embodiment of this disclosure.

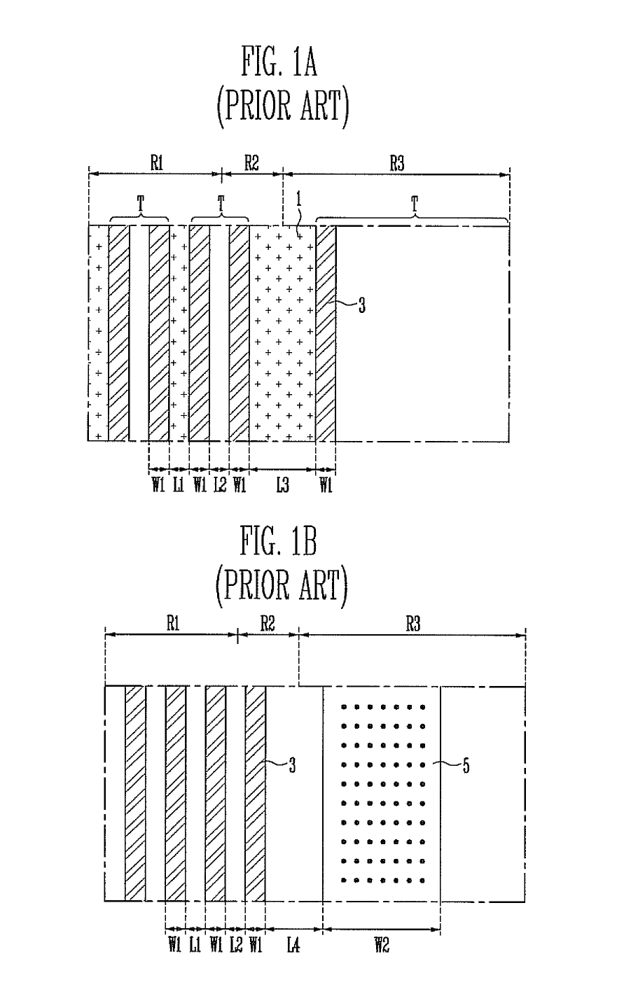

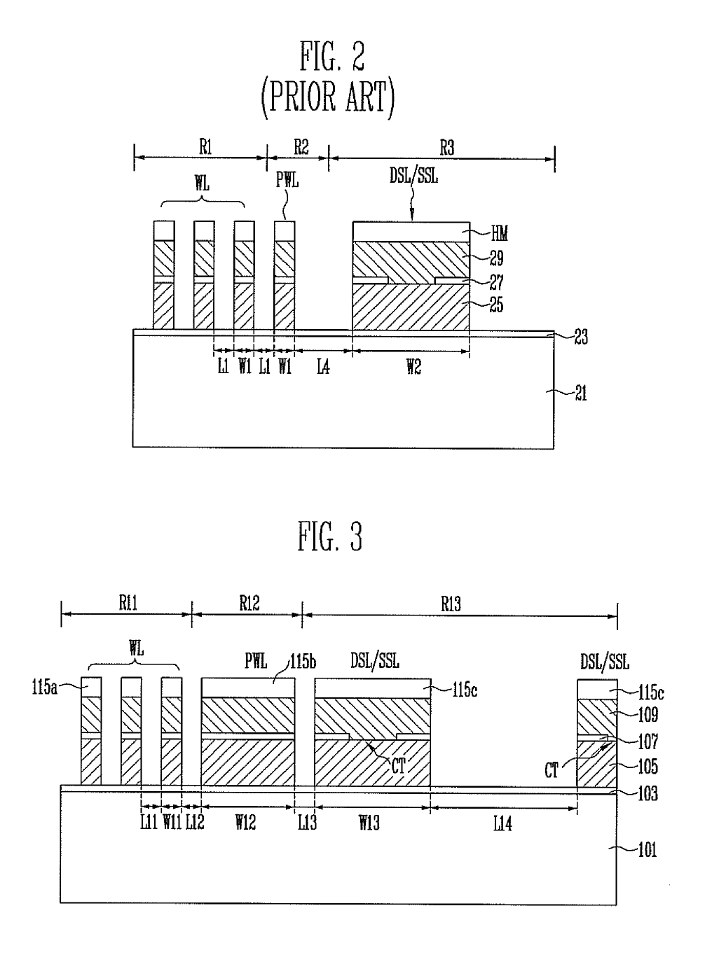

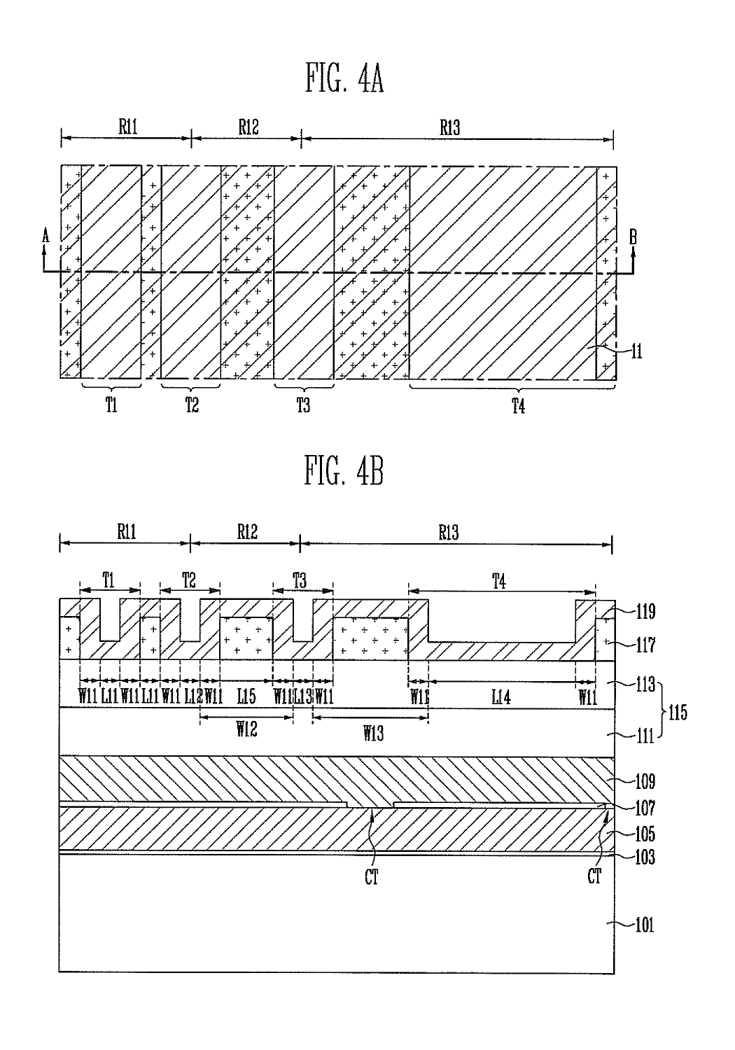

### DESCRIPTION OF EMBODIMENTS

Hereinafter, some exemplary embodiments of the present disclosure will be described in detail with reference to the accompanying drawings. The figures are provided to enable those of ordinary skill in the art to make and use the present invention according to the exemplary embodiments of the present invention.

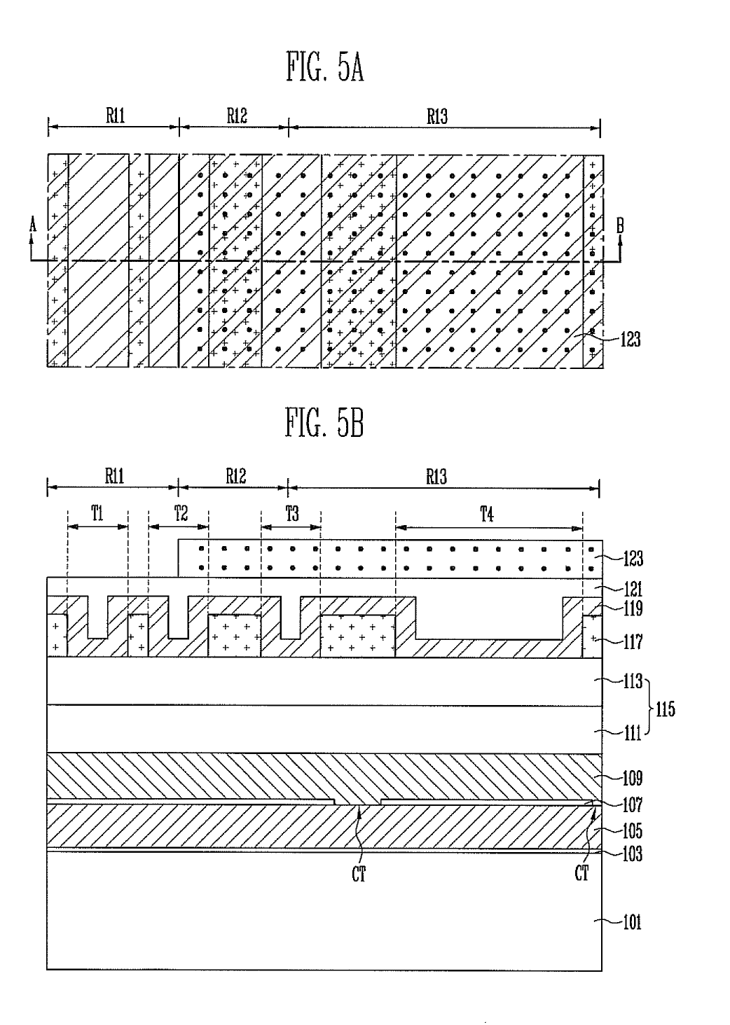

FIG. 3 is a cross-sectional view illustrating some of the patterns of a semiconductor device according to an embodiment of this disclosure. More particularly, FIG. 3 is a cross-sectional view showing some of the gate lines of a NAND flash memory device.

Referring to FIG. 3, the gate lines of the NAND flash memory device include word lines WL formed in a first region R11, a dummy word line PWL formed in a second region R12, and a select line DSL/SSL formed in a third region R13. The first region R11 may be a memory cell region where memory cells for storing data are formed. The word lines WL are coupled to the respective memory cells. The second region R13 is disposed between the first region R11 and the third region R13 and may be a region where a dummy element for preventing an occurrence of a disturbance phenomenon is formed. The dummy word line PWL is coupled to the dummy element. The third region R13 may be a region where a source select transistor or a drain select transistor for selecting the memory string of the NAND flash memory device is formed. The select line DSL/SSL may be a source select line SSL coupled to the source select transistor or a drain select line DSL coupled to the drain select transistor.

The gate line may be formed by patterning stack layers 103, 105, 107, and 109 over a semiconductor substrate 101, including isolation regions (not shown) and active regions by using first to third hard mask patterns HM as an etch mask. The stack layers include a gate insulating layer 103 and a first conductive layer 105 stacked over the active regions of the semiconductor substrate 101, a dielectric layer 107 formed over the first conductive layer 105 and formed to include a contact hole CT through which the first conductive layer 105 is exposed in the third region R13, and a second conductive layer 109 formed on the dielectric layer 107.

The word lines WL, the dummy word line PWL, and the select line DSL/SSL are formed of the patterned second conductive layer 109. The first conductive layers 105 formed under the word lines WL of the first region R11 with the dielectric layers 107 interposed therebetween are used as the floating gates of the NAND flash memory device. The first conductive layer 105 formed under the select line DSL/SSL and electrically coupled to the select line DSL/SSL through the contact hole CT formed in the dielectric layer 107 is used as the gate of the select transistor. Furthermore, the first conductive layer 105 formed under the dummy word line PWL with the dielectric layer 107 interposed therebetween becomes a dummy floating gate.

In an embodiment of the present invention, a width W11 of the word line WL is defined by the width of a first hard mask pattern 115a, a width W12 of the dummy word line PWL is defined by the width of a second hard mask pattern 115b, and a width W13 of the select line DSL/SSL is defined by the width of the third hard mask pattern 115c. Furthermore, an interval L11 between the word lines WL is defined by an interval between the first hard mask patterns 115a. An interval between the word line WL and the select line DSL/SSL is defined by the sum of an interval L12 between the word line WL and the dummy word line PWL, the width W12 of the dummy word line PWL, and an interval between L13 between the dummy word line PWL and the select line DSL/SSL. The interval L12 between the word line WL 10, and the dummy word line PWL is defined by an interval between the first and the second hard mask patterns 115a and 115b. The interval L13 between the dummy word line PWL and the select line DSL/SSL is defined by an interval between the second and the third hard mask patterns 115b and 115c. Accordingly, in order to reduce an error value of the interval between the word line WL and the select line DSL/SSL, error values of the interval between the first and the second hard mask patterns 115a and 115b and the interval between the second and the third hard mask patterns 115b and 115c are to be reduced. In exemplary embodiments of the present invention, a process of reducing the error value of an interval between the second and the third hard mask patterns 115b and 115c is performed. Here, reducing the error value of the interval means that the interval may be prevented from having a different value from a design value due to the factors of fabrication processes, e.g. an alignment error of the exposure masks. According to the embodiments, the width W12 of the dummy word line PWL is wider than the width W11 of the word line WL. Furthermore, in exemplary embodiments of the present invention, the interval L12 between the word line WL and the dummy word line PWL and the interval L13 between the select line DSL/SSL and the dummy word line PWL may be the same as the interval L11 between the word lines WL. Meanwhile, as in typical NAND flash memory devices, in exemplary embodiments of the present invention, an interval L14 between the select lines DSL/SSL is wider than the interval L11 between the word lines WL, and the width W13 of the select line DSL/SSL is wider than the width W11 of the word line WL.

A method of forming the patterns of the semiconductor device for reducing the error values of an interval between the first and the second hard mask patterns 115a and 115b and an interval between the second and the third hard mask patterns 115b and 115c according to a first embodiment of the present invention is described in detail with reference to FIG. 4A to 8B.

FIGS. 4A to 8B are diagrams illustrating the method of forming the patterns of the semiconductor device according to the first embodiment of the present invention. More particularly, FIGS. 4A to 8B show the method of forming the gate lines of the NAND flash memory device as an example. FIGS. 4A, 5A, 6A, 7A, and 8A are plan views of the method, and FIGS. 4B, 5B, 6B, 7B, and 8B are cross-sectional views taken along line A-B of the respective FIGS. 4A, 5A, 6A, 7A, and 8A.

Referring to FIGS. 4A and 4B, a hard mask layer 115 is formed over the stack layers 103, 105, 107, and 109 including the first to third region R11, R12, and R13 which are arranged in a row.

The stack layers 103, 105, 107, and 109 include the gate insulating layer 103, the first conductive layer 105, the dielectric layer 107, and the second conductive layer 109 which are stacked over the semiconductor substrate 101, including the isolation regions (not shown) and the active regions partitioned by the isolation regions. The gate insulating layer 103 and the first conductive layer 105 may be formed over the active regions of the semiconductor substrate 101, and the dielectric layer 107 and the second conductive layer 109 may be formed over the active regions and the isolation regions of the semiconductor substrate 101. The contact hole CT through which the first conductive layer 105 is coupled to the second conductive layer 109 is formed in the dielectric layer 107 of the third region R13.

Before forming the dielectric layer 107, the gate insulating layer 103 and the first conductive layer 105 over the isolation regions, from the gate insulating layer 103 and the first conductive layer 105 stacked over the semiconductor substrate 101 including the active regions and the isolation regions, may be removed by an etch process. Next, trenches are formed by etching the isolation regions of the semiconductor substrate 101, and an isolation layer is formed within the trenches. In the process of forming the isolation layer as described above, the gate insulating layer 103 and the first conductive layer 105 may be removed from the upper sides of the isolation regions of the semiconductor substrate 101, but may remain over the active regions of the semiconductor substrate 101.

The gate insulating layer 103 may be formed of a silicon oxide layer, and the first conductive layer 105 may be formed of a polysilicon layer. The dielectric layer 107 including the contact hole CT may be formed by stacking an oxide layer, a nitride layer, and an oxide layer and then removing part of the dielectric layer 107 formed in the third region R13 by an etch process. The second conductive layer 109 may be formed of any one of a polysilicon layer, a metal layer, and a metal silicide layer or may be formed of at least two of the polysilicon layer, the metal layer, and the metal silicide layer.

The hard mask layer 115 functions as an etch mask in an etch process of forming the gate lines. The hard mask layer 115 may be formed of a single layer or a plurality of stack layers by taking an etch selectivity to the second conductive layer 109 into consideration. For example, the hard mask layer 115 may be formed by stacking an oxide layer 111 and a polysilicon layer 113.

After forming a first auxiliary layer 117 on the hard mask layer 115, the first auxiliary layer 117 is etched to form first to fourth trenches T1, T2, T3, and T4. The first to fourth trenches T1, T2, T3, and T4 may be formed by forming the first auxiliary layer 117 on the hard mask layer 115 and then etching part of the first auxiliary layer 117 by an etch process and a photolithography process employing one exposure mask. Since the regions where the first to fourth trenches T1, T2, T3, and T4 are formed are defined by the photolithography process employing one exposure mask, the first to fourth trenches T1, T2, T3, and T4 may be formed to have desired widths and intervals without an error.

The first trenches T1 are disposed in the first region R11, the second trench T2 is disposed at the boundary of the first region R11 and the second region R12, the third trench T3 is disposed at the boundary of the second region R12 and the third region R13, and the fourth trench T4 is disposed in the third region R13. Each of the first trenches T1 has a first width, and the first trenches T1 are spaced apart from one another at first intervals. The first width may be three times the first interval in order to make uniform the interval between the word lines to be subsequently formed. The second trench T2 may have the first width in order to make the interval between the word line and the dummy word line to be subsequently formed identical with the interval between the word lines. An interval between the first trench T1 and the second trench T2 may be identical with the first interval in order to make uniform the interval between the word lines. The third trench T3 may have the first width in order to make identical the interval between the dummy word line and the select line to be subsequently formed with the interval between the word lines. An interval between the second trench T2 and the third trench T3 may be equal to or greater than the first interval depending on the width of the dummy word line. The fourth trench T4 may have a width wider than the first width in order to make the interval between the select lines to be subsequently formed wider than the interval between the word lines. An interval between the third trench T3 and the fourth trench T4 may be equal to or greater than the first interval depending on the width of the select lines to be formed.

The first auxiliary layer 117 may be formed of material which is selected by taking the selectivity between a layer formed over the first auxiliary layer 117 and a layer formed under the first auxiliary layer 117 into consideration. For example, the first auxiliary layer 117 may be formed of a spin on carbon (SOC) layer.

A second auxiliary layer 119 is formed on the entire surface of the structure including the first to fourth trenches T1, T2, T3, and T4. It is preferred that the second auxiliary layer 119 be formed to have a proper thickness not to fully fill the first to fourth trenches T1, T2, T3, and T4. Here, the thickness of the second auxiliary layer 119 formed on each of the sidewalls of the first to fourth trenches T1, T2, T3, and T4 influences/determines the width of the word line, the width of the dummy word line, and the width of the select line. Furthermore, the width of a hole portion within each of the first to fourth trenches T1, T2, T3, and T4 not filled with the second auxiliary layer 119 influences an interval between the word lines, an interval between the word line and the dummy word line, an interval between the dummy word line and the select line, and an interval between the select lines. In the first embodiment, in order to make the width of the word line, the interval between the word lines, the interval between the word line and the dummy word line, and the interval between the dummy word line and the select line identical with each other, the thickness of the second auxiliary layer 119 may be identical with the first interval that is the interval between the first trenches T1. The deposition thickness of the second auxiliary layer 119 may be controlled by controlling a deposition process condition. Furthermore, it is preferred that the second auxiliary layer 119 be formed of different material from the first auxiliary layer 117 by taking an etch selectivity to the first auxiliary layer 117 into consideration. For example, the second auxiliary layer 119 may be formed of an oxide layer.

Referring to FIGS. 5A and 5B, a third auxiliary layer 121 is formed on the second auxiliary layer 119 to fill the first to fourth trenches T1, T2, T3, and T4. A protection pattern 123 is formed on the third auxiliary layer 121.

It is preferred that the third auxiliary layer 121 be formed of different material from the second auxiliary layer 119 by taking an etch selectivity to the second auxiliary layer 119 into consideration. Furthermore, the third auxiliary layer 121 is formed of material which is flowable-fill and coatable for anti-reflection and planarization. For example, the third auxiliary layer 121 may be formed of an organic substance for anti-reflection (for example, a bottom anti-reflection coating (BARC) layer) or may be formed of a spin on carbon (SOC) layer. If the third auxiliary layer 121 is formed of the spin on carbon (SOC) layer, a fourth auxiliary layer formed of SiON may be further formed on the third auxiliary layer 121 in order to prevent the third auxiliary layer 121 from being stripped by a process of stripping subsequent photoresist patterns.

The protection pattern 123 may be a photoresist pattern formed of photoresist material. The protection pattern 123 functions to prevent the first auxiliary layer 117, placed between the second and the third trenches T2 and T3 and between the third and the fourth trenches T3 and T4, from being exposed in a process of exposing the first auxiliary layer 117 on both sides of the first trench T1. It is preferred that the protection pattern 123 be formed to cover the second and the third regions T2 and T3. In particular, in the exemplary embodiment, the edge of the protection pattern 123 may be disposed on the third auxiliary layer 121 in the region of the second trench T2. The third auxiliary layer 121 in the first region R11 is exposed through the protection pattern 123. The width of the second trench T2 may be wide enough to secure an alignment margin of the protection pattern 123. The width of the second trench T2 may have various values according to a design rule.

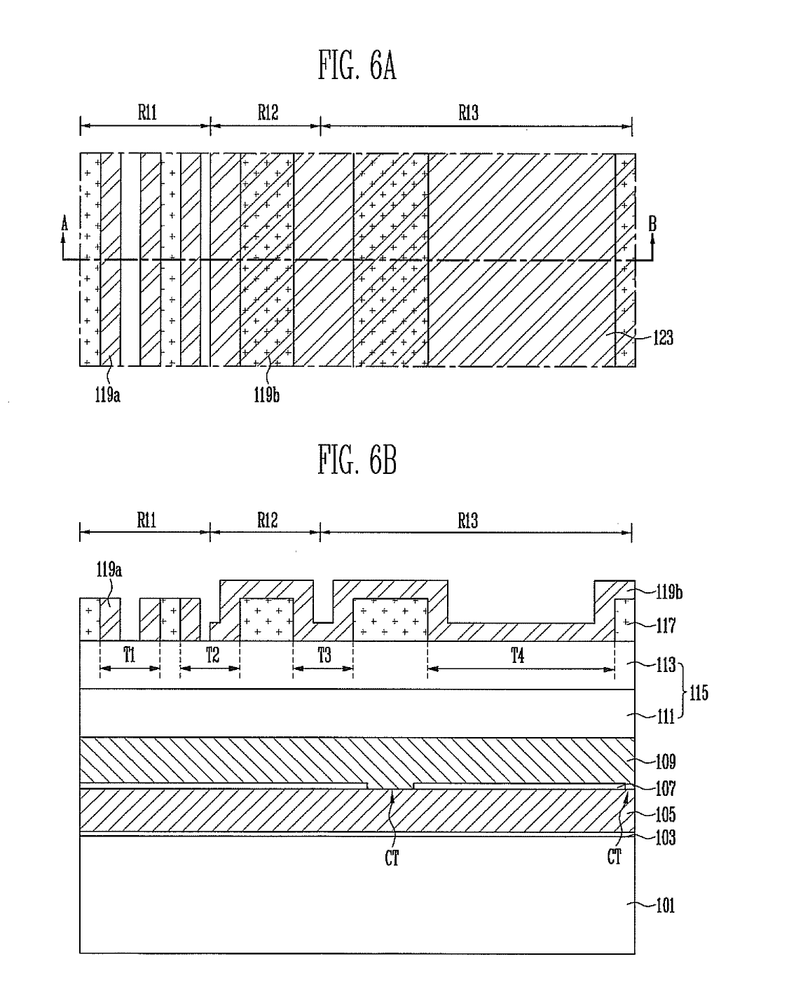

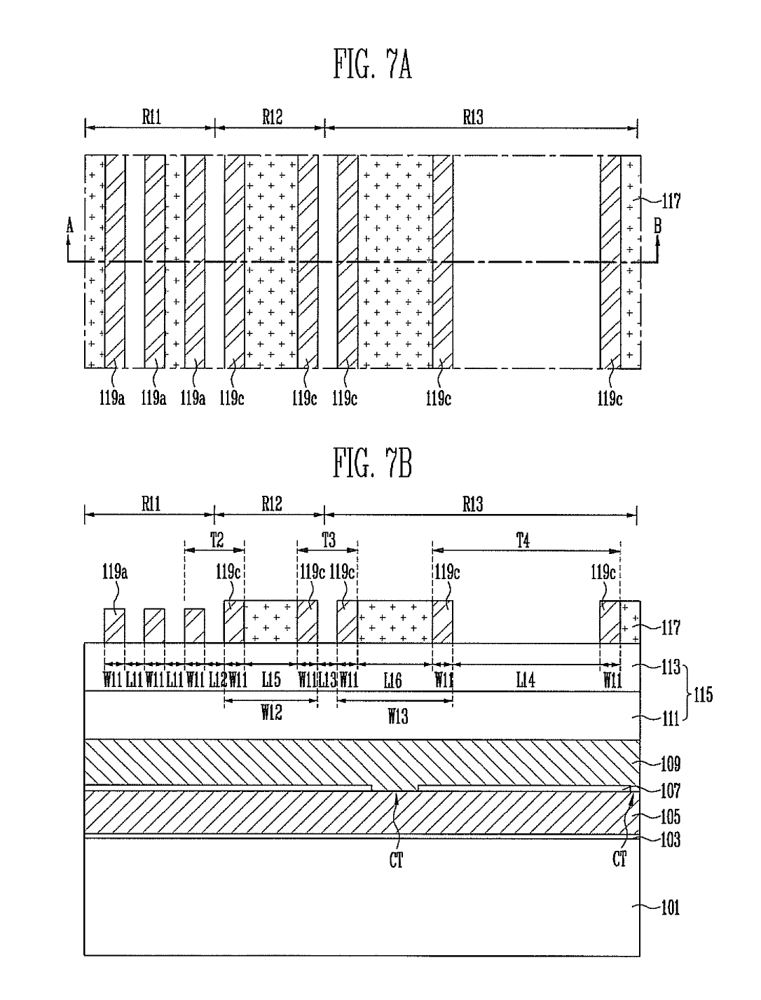

Referring to FIGS. 6A and 6B, the exposed region of the third auxiliary layer 121 are removed by an etch process using the protection pattern 123 as an etch mask, thereby exposing the second auxiliary layer 119. Next, the second auxiliary layer 119 is removed by performing a primary etch process on the second auxiliary layer 119, thereby forming first spacers 119a on the sidewalls of the first auxiliary layer 117 in the first region R11.

The primary etch process of the second auxiliary layer 119 is performed by removing the exposed region of the second auxiliary layer 119 by a specific thickness so that the top surfaces of the first auxiliary layers 117 in the first region R11 are exposed and the hard mask layer 115 is exposed through the bottom surfaces of the first trenches T1. Consequently, the second auxiliary layer 119 remains on the sidewalls of the first trenches T1 in the first region R11 and on the sidewall of the second trench T2 neighboring the first region R11 as the spacers 119a.

Next, the protection pattern 123 and the remaining regions of the third auxiliary layer 121 are removed. In the primary etch process of the second auxiliary layer 119, a second auxiliary layer 119b in the second and the third regions R12 and R13 is not removed because the second auxiliary layer 119b is protected by the third auxiliary layer 121.

Referring to FIGS. 7A and 7B, the exposed regions of the first auxiliary layer 117 may be removed by an etch process. In the process of removing the exposed regions of the first auxiliary layer 117, the first auxiliary layer 117 of the second and the third regions R11 and R12 are protected by the second auxiliary layer (refer to 119b of FIG. 6B) and are not removed. Since the exposed regions of the first auxiliary layer 117 are removed from the first region R11, the first spacers 119a of the first region R11 are spaced apart from one another.

After removing the exposed regions of the first auxiliary layer 117, the second auxiliary layer are etched by performing a secondary etch process on the second auxiliary layer, so that second spacers 119c are formed on the sidewall of the second trench T2 neighboring the second region R12 and on the sidewalls of the third and the fourth trenches T3 and T4. The secondary etch process on the second auxiliary layer is performed by removing part of the second auxiliary layer so that the second auxiliary layer remain on the sidewalls of the second to fourth trenches T2, T3, and T4 and in the first region R11, but the hard mask layer 115 is exposed at the bottom surfaces of the second to fourth trenches T2, T3, and T4.

As a result of the secondary etch process, the first patterns comprising first spacers 119a in the first region R11, second patterns comprising the first auxiliary layer 117 and the second spacers 119c on both sides thereof in the second region R12, and third patterns comprising the first auxiliary layer 117 and the second spacers 119c on both sides thereof in the third region R13 are self-aligned. The etch process of the third auxiliary layer 121 and the secondary etch process of the second auxiliary layer may be performed in-situ.

Each of the first patterns defines the width of the first hard mask pattern for defining a region where the word line will be formed. Each of the second patterns defines the width of the second hard mask pattern for defining a region where the dummy word line will be formed. Each of the third patterns defines the width of the third hard mask pattern for defining a region where the select line will be formed.

In the secondary etch process of the second auxiliary layer, the height of the first spacers 119a in the first region R11 may be lowered. The height of the first auxiliary layer 117 is greater than the etch thickness of the second auxiliary layer. Thus, the first spacers 119a having the height determined by the height of the first auxiliary layer 117 are not removed by the secondary etch process of the second auxiliary layer.

Some regions of the hard mask layer 115 are exposed, but the remaining regions thereof are blocked by the first to third patterns. In the first embodiment, the widths and intervals of the first to third patterns are defined by a deposition thickness W11 of the second auxiliary layer and intervals L11, L12, L13, L14, L15, and L16 which are defined by the intervals and widths of the first to fourth trenches T1, T2, T3, and T4 and the deposition thickness W11 of the second auxiliary layer. The intervals of the first to fourth trenches T1, T2, T3, and T4 and the deposition thickness W11 of the second auxiliary layer are not changed by a shift or misalignment of the exposure masks. According to the present embodiment, error values of the widths and intervals of the exposed regions and blocked regions of the hard mask layer 115 may be reduced by the first to third patterns.

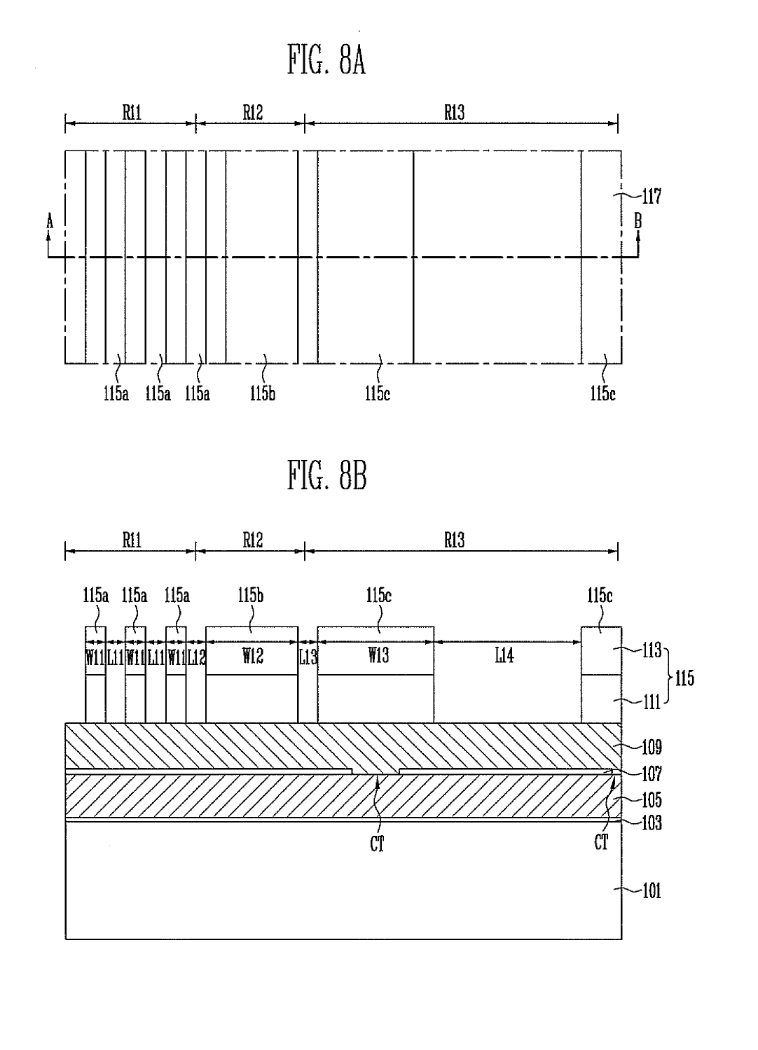

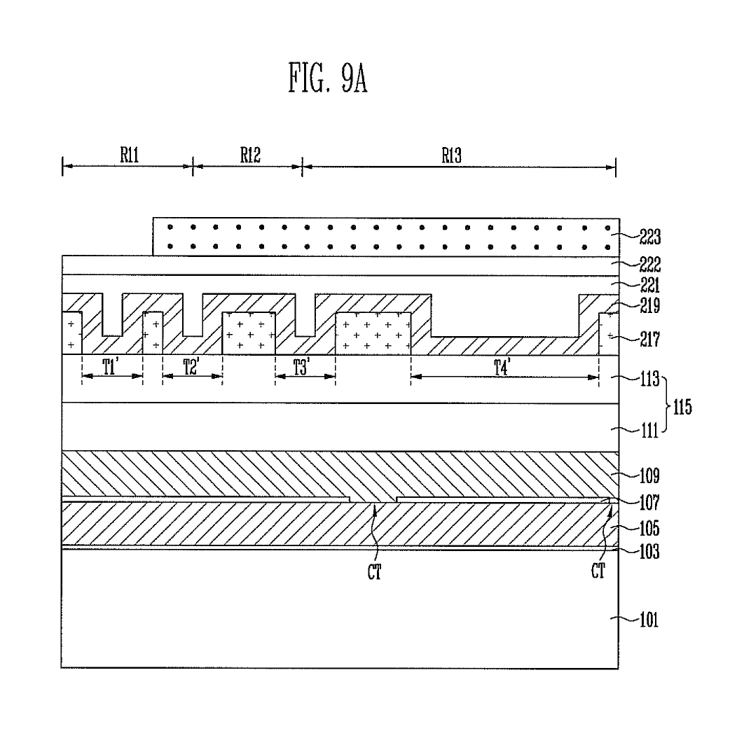

Referring to FIGS. 8A and 8B, the exposed regions of the hard mask layer are removed by performing an etch process using the first to third patterns as an etch mask, thereby forming first to third hard mask patterns 115a, 115b, and 115c. Next, the remaining first to third patterns (that is, the remaining first and the second auxiliary layers) are removed.

According to the first embodiment, an interval between the first and the second hard mask patterns 115a and 115b, an interval between the second and the third hard mask patterns 115b and 115c, and the width of each of the first to third hard mask patterns 115a, 115b, and 115c are determined by the deposition thickness of the second auxiliary layer and the patterning process of the first auxiliary layer for forming the first to fourth trenches in the first auxiliary layer. The first to fourth trenches may be formed regardless of an alignment error of the exposure masks. According to the first embodiment, in forming an interval between the first and the second hard mask patterns 115a and 115b, an interval between the second and the third hard mask patterns 115b and 115c, and the width of each of the first to third hard mask patterns 115a and 115b, and 115c, errors may be prevented from occurring due to an alignment error of the exposure masks.

The word lines WL, the dummy word line PWL, and the select line DSL/SSL of FIG. 3 may be formed by pattering the stack layers 109, 107, and 105 using the first to third hard mask patterns 115a, 115b, and 115c as an etch mask.

As described above, in the first embodiment, the interval between the select line and the word line may be controlled by the widths and intervals of the first to fourth trenches, defined by the photolithography process using one exposure mask, and the deposition thickness of a deposition layer (that is, the second auxiliary layer). Consequently, the interval between the select line and the word line may be prevented from being changed from a design value due to an alignment error of different exposure masks.

Furthermore, in the first embodiment, an interval between the first hard mask patterns, an interval between the first and the second hard mask patterns, and an interval between the second and the third hard mask pattern may be made identical with each other by controlling the widths and intervals of the first to fourth trenches and the thickness of the deposition layer. In this case, the etch rate may become uniform when the exposed regions of the stack layers are etched because the width of each of the stack layers exposed between the first hard mask patterns, between the first and the second hard mask patterns, and between the second and the third hard mask patterns may become uniform. Consequently, damage to the gate insulating layer and the active regions, generated because the etch rate becomes irregular owing to a difference in the widths of the regions exposed through the hard mask pattern, may be prevented from being caused.

Furthermore, in the first embodiment, the width of the dummy word line formed to prevent an occurrence of disturbance may be controlled to have a desired width by controlling the interval between the first and the second trenches.

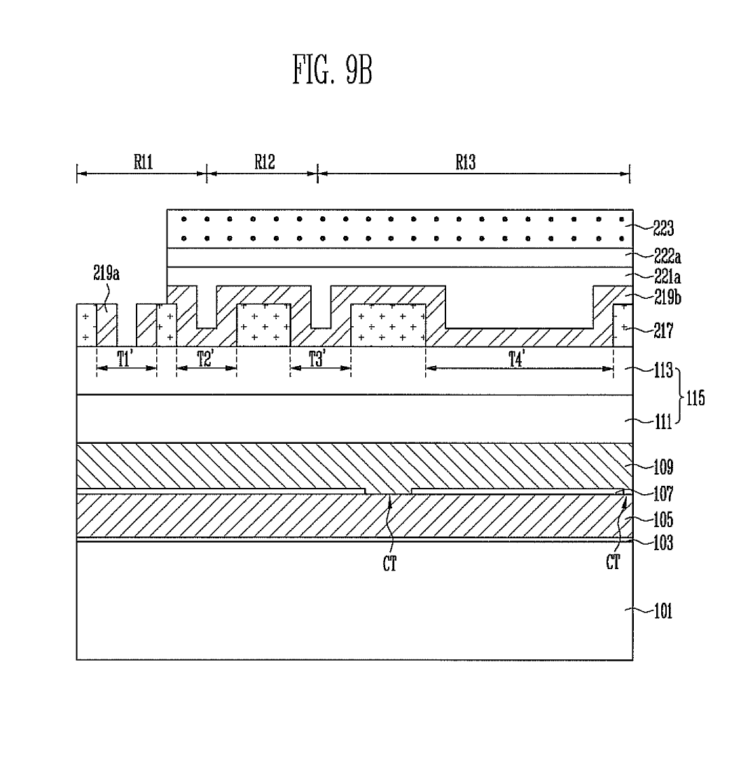

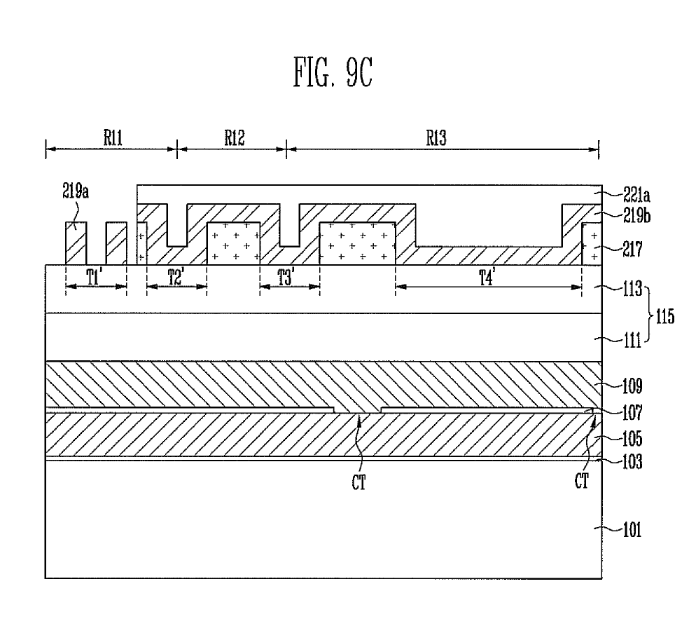

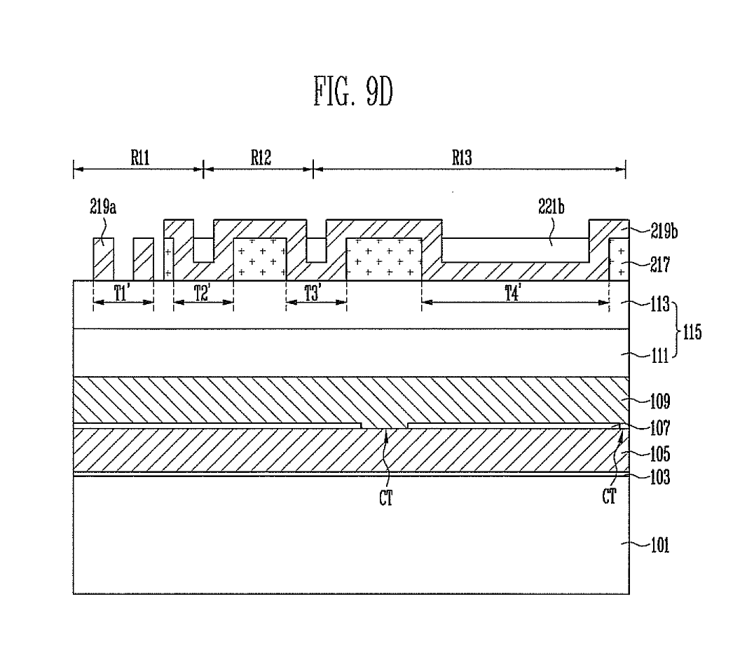

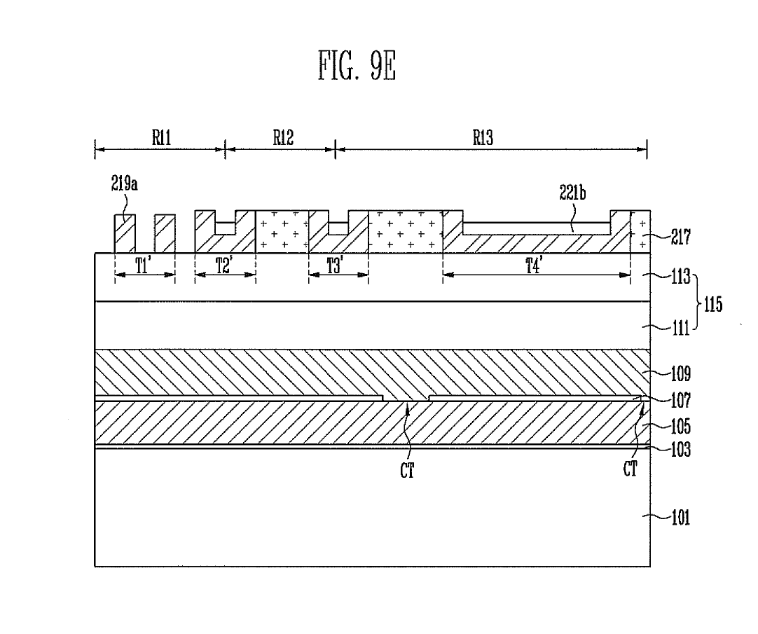

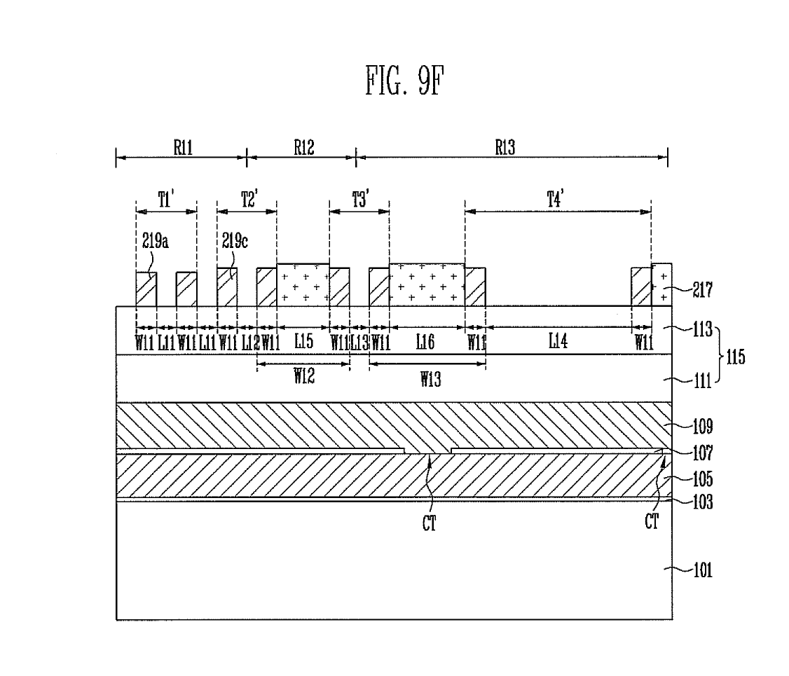

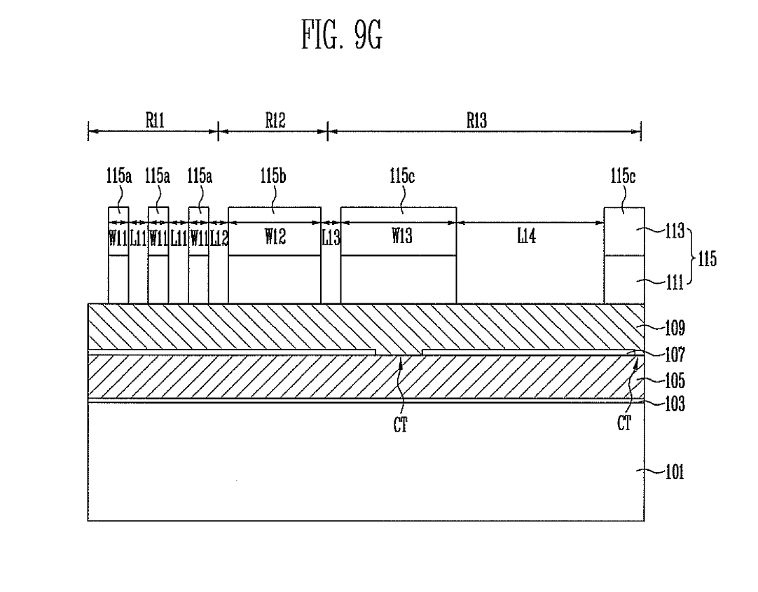

FIGS. 9A to 9G are cross-sectional views illustrating a method of forming the patterns of a semiconductor device according to a second embodiment of the present invention. More particularly, FIGS. 9A to 9G are cross-sectional views illustrating a method of forming the gate lines of the NAND flash memory device shown in FIG. 3. In FIGS. 9A to 9G, in order to reduce an error value of an interval between the word line and the select line shown in FIG. 3, error values of an interval between the first and the second hard mask patterns (115a and 115b of FIG. 3) and an interval between the second and the third hard mask patterns (115b and 115c of FIG. 3) is reduced.

Referring to FIG. 9A, a hard mask layer 115 is formed over stack layers 103, 105, 107, and 109 including first to third regions R11, R12, and R13 which are arranged in a row.

The stack layers 103, 105, 107, and 109 are the same as those of FIGS. 4A and 4B, and a detailed description thereof is omitted.

The hard mask layer 115 functions as an etch mask in an etch process of forming the gate line, as described above with reference to FIGS. 4A and 4B. The hard mask layer 115 may be formed of a single layer or a plurality of stack layers by taking an etch selectivity to the second conductive layer 109 into consideration. For example, the hard mask layer 115 may be formed by staking an oxide layer 111 and a polysilicon layer 113.

A first auxiliary layer 217 is formed on the hard mask layer 115 and then etched to form first to fourth trenches T1′, T2′, T3′, and T4′, The first to fourth trenches T1′, T2′, T3′, and T4′ may be formed by forming the first auxiliary layer 217 on the hard mask layer 115 and then etching part of the first auxiliary layer 217 by using a photolithography process employing one exposure mask and an etch process, Regions where the first to fourth trenches T1′, T2′, T3′, and T4′ will be formed are defined by the photolithography process employing one exposure mask. Accordingly, the first to fourth trenches T1′, T2′, T3′, and T4′ may be formed to have desired widths and intervals without an error.

The first trenches T1′ are disposed in the first region R11. The second trench T2′ is disposed at the boundary of the first region R11 and the second region R12. The third trench T3′ is disposed at the boundary of the second region R12 and the third region R13. The fourth trenches T4′ are disposed in the third region R13. Each of the first trenches T1′ has a first width, and the first trenches T1′ are spaced apart from one another at first intervals. The first width may be three times the first interval so that intervals between the word lines to be subsequently formed are the same each other. The second trench T2′ may have the first width in order to make the interval between the word line and the dummy word line to be subsequently formed identical with the interval between the word lines. An interval between the first trench T1′ and the second trench T2′ may be identical with the first interval in order to make uniform the interval between the word lines. The third trench T3′ may have the first width in order to make identical the interval between the dummy word line and the select line to be subsequently formed with the interval between the word lines. An interval between the second trench T2′ and the third trench T3′ may be equal to or greater than the first interval depending on the width of the dummy word line. The fourth trench T4′ may have a width wider than the first width in order to make the interval between the select lines to be subsequently formed wider than the interval between the word lines. An interval between the third trench T3′ and the fourth trench T4′ may be equal to or greater than the first interval depending on the width of the select lines to be formed.

The first auxiliary layer 217 may be formed of material which is selected by taking the selectivity between a layer formed over the first auxiliary layer 217 and a layer formed under the first auxiliary layer 217 into consideration. For example, the first auxiliary layer 217 may be formed of a spin on carbon (SOC) layer.

A second auxiliary layer 219 is formed on the entire surface of the structure including the first to fourth trenches T1′, T2′, T3′, and T4′. It is preferred that the second auxiliary layer 219 be formed to have a proper thickness not to fully fill the first to fourth trenches T1′, T2′, T3′, and T4′. Here, the thickness of the second auxiliary layer 219 formed on each of the sidewalk of the first to fourth trenches T1′, T2′, T3′, and T4′ influences the width of the word line, the width of the dummy word line, and the width of the select line. Furthermore, the width of a hole portion within each of the first to fourth trenches T1′, T2′, T3′, and T4′ not filled with the second auxiliary layer 219 influences an interval between the word lines, an interval between the word line and the dummy word line, an interval between the dummy word line and the select line, and an interval between the select lines. In the second embodiment, in order to make the width of the word line, the interval between the word lines, the interval between the word line and the dummy word line, and the interval between the dummy word line and the select line identical with each other, the thickness of the second auxiliary layer 219 may be identical with the first interval that is the interval between the first trenches T1′. The deposition thickness of the second auxiliary layer 219 may be controlled by controlling a deposition process condition. Furthermore, it is preferred that the second auxiliary layer 219 be formed of different material from the first auxiliary layer 217 by taking an etch selectivity to the first auxiliary layer 217 into consideration. For example, the second auxiliary layer 219 may be formed of an oxide layer.

A third auxiliary layer 221 is formed on the second auxiliary layer 219 to fill the first to fourth trenches T1′, T2′, T3′, and T4′. A protection pattern 223 is formed over the third auxiliary layer 221.

It is preferred that the third auxiliary layer 221 be formed of different material from the second auxiliary layer 219 by taking an etch selectivity to the second auxiliary layer 219 into consideration. Furthermore, the third auxiliary layer 221 is formed of material which is flowable-fill and coatable for anti-reflection and planarization. For example, the third auxiliary layer 221 may be formed of an organic substance for anti-reflection (for example, a bottom anti-reflection coating (BARC) layer) or may be formed of a spin on carbon (SOC) layer. If the third auxiliary layer 221 is formed of the spin on carbon (SOC) layer, a fourth auxiliary layer 222 formed of SiON or multi-function hard mask (MFHM) material may be further formed on the third auxiliary layer 221 in order to prevent the third auxiliary layer 221 from being stripped by a process of stripping subsequent photoresist patterns.

The protection pattern 223 may be a photoresist pattern formed of photoresist material. The protection pattern 223 functions to prevent the first auxiliary layer 217, placed between the second and the third trenches T2′ and T3′ and between the third and the fourth trenches T3′ and T4′, from being exposed in a process of exposing the first auxiliary layer 217 on both sides of the first trench T1′. It is preferred that the protection pattern 223 be formed to cover the second and the third regions T2′ and T3′, In particular, in the present embodiment, the edge of the protection pattern 223 may be disposed on the fourth auxiliary layer 222 in the region between the first and the second trenches T1′ and T2′ or in the region of the second trench T2′. The fourth auxiliary layer 222 in the first region R11 is exposed through the protection pattern 223. The sum of the width of the second trench T2′ and the width of the first auxiliary layer 217 between the first and the second trenches T1′ and T2′ may be formed to be wide enough to secure an alignment margin of the protection pattern 223.

Referring to FIG. 9B, the exposed region of the fourth auxiliary layer 222 is removed by performing an etch process using the protection pattern 223 an etch mask, thereby exposing the third auxiliary layer 221. Next, the second auxiliary layer 219 is exposed by removing the exposed region of the third auxiliary layer 221 using an etch process. Next, the second auxiliary layer 219 is removed by performing a primary etch process on the second auxiliary layer 219, thereby forming first spacers 219a on the sidewalls of the first trenches T1′.

The primary etch process of the second auxiliary layer 219 is performed by etching the exposed region of the second auxiliary layer 219 by a specific thickness so that the top surface of the first auxiliary layer 217 between the first trenches T1′ is exposed and the hard mask layer 115 is exposed through the bottom surfaces of the first trenches T1′. Furthermore, in the primary etch process, a second auxiliary layer 219b in the second and the third regions R12 and R13 is not removed because the second auxiliary layer 219b is protected by a third auxiliary layer 221a. The edge of the remaining third auxiliary layer 221a is placed on the region between the first and the second trenches T1′ and T2′ or the region of the second trench T2′ like the edge of the protection pattern 223. Furthermore, the third auxiliary layer 221a covers the second auxiliary layer 219b in the second and the third regions R12 and R13.

Referring to FIG. 9C, the exposed regions of the first auxiliary layer 217 are removed. In the process of removing the exposed regions of the first auxiliary layer 217, the first auxiliary layer 217 of the second and third regions R12 and R13 are protected by the second auxiliary layer 219b and are not removed. Meanwhile, if the edge of the third auxiliary layer 221a is placed on the region between the first and the second trenches T1′ and T2′, part of the first auxiliary layer 217 between the first and the second trenches T1′ and T2′ may not be removed because it is protected by the second auxiliary layer 219b protected by the third auxiliary layer 221a.

The protection pattern 223 and the fourth auxiliary layer 222 are removed before removing the third auxiliary layer 221a.

Referring to FIG. 9D, the third auxiliary layer 221a is etched. The third auxiliary layer 221a is partially etched by a specific thickness so that the second auxiliary layer 219b is exposed between the first and the second trenches T1′ and T2′, between the second and the third trenches T2′ and T3′, and between the third and the fourth trenches T3′ and T4′ and the third auxiliary layer 221b remains in the second to the fourth trenches T2′, T3′, and T4′.

Referring to FIG. 9E, part of the second auxiliary layer is removed by performing a secondary etch process on the second auxiliary layer. The secondary etch process of the second auxiliary layer is performed by removing the second auxiliary layer by a specific thickness so that the top surfaces of the first auxiliary layers 217 are exposed and the first spacers 219a remain.

Next, the first auxiliary layers 217 are partially etched so that the first auxiliary layer 217 remaining in the first region R11 is removed, but the first auxiliary layers 217 remain in the second and the third regions R12 and R13. The amount of the first auxiliary layer 217 remaining in the first region R11 is smaller than the amount of the first auxiliary layers 217 remaining in the second and the third regions R12 and R13. Accordingly, although the first auxiliary layer 217 remaining in the first region R11 is removed, the first auxiliary layers 217 remaining in the second and the third regions R12 and R13 may remain without being fully removed. When the first auxiliary layer 217 remaining in the first region R11 is removed, the first spacers 219a in the first region R11 are spaced apart from one another.

Referring to FIG. 9F, the second auxiliary layer 219b formed at the bottom surfaces of the second to the fourth trenches T2′, T3′, and T4′ are exposed by removing the third auxiliary layers 221b. Next, part of the second auxiliary layer is removed by performing a tertiary etch process on the second auxiliary layer, thereby forming second spacers 219c on the sidewalls of the second to the fourth trenches T2, T3, and 14.

The tertiary etch process of the second auxiliary layer is performed by removing part of second auxiliary layer so that the first spacers 219a remain and the hard mask layer 115 is exposed through the bottom surfaces of the second to fourth trenches T2′, T3′, and T4′. As a result of the tertiary etch process, in the first region R11, not only the first spacers 219a are spaced apart from one another, but also the second spacer 219c is spaced apart from the first spacer 219a and another second spacer 219c. The first and the second spacers 219a and 219c spaced apart from each other in the first region R11 are called first patterns.

Furthermore, as a result of the tertiary etch process, second patterns, including the auxiliary layer 217 and the second spacers 219c formed on both sides thereof in the second region R12, and third patterns including the auxiliary layers 217 and the second spacers 219c formed on both sides of the auxiliary layer 217 in the third region R13 are self-aligned along with the first patterns. The etch process of the third auxiliary layer 221b and the tertiary etch process of the second auxiliary layer may be performed in-situ.

Each of the first patterns in the first region R11 defines the width of the first hard mask pattern for defining a region where the word line will be formed. The second pattern defines the width of the second hard mask pattern for defining a region where the dummy word line will be formed. The third pattern defines the width of the third hard mask pattern for defining a region where the select line will be formed.

In the tertiary etch process, the height of the first spacers 219a in the first region R11 may be lowered. The height of the first auxiliary layers 217 is higher than the etch thickness of the second auxiliary layer. Thus, the first spacers 219a having the height determined by the height of the first auxiliary layer 217 is not removed in the tertiary etch process.

Some regions of the hard mask layer 115 are exposed, but the remaining regions thereof are blocked by the first to third patterns. In the second embodiment, the widths and intervals of the first to third patterns are defined by a deposition thickness W11 of the second auxiliary layer and intervals L11, L12, L13, L14, L15, and L16 which are defined by the intervals and widths of the first to fourth trenches T1′, T2′, T3′, and T4′ and the deposition thickness W11 of the second auxiliary layer. The intervals of the first to fourth trenches T1′, T2′, T3′, and T4′ and the deposition thickness W11 of the second auxiliary layer are not changed by a shift or misalignment of the exposure masks. According to the present embodiment, error values of the widths and intervals of the exposed regions and blocked regions of the hard mask layer 215 may be reduced by the first to third patterns.

Referring to FIG. 9G, the exposed regions of the hard mask layer are removed by performing an etch process using the first to third patterns as an etch mask, thereby forming first to third hard mask patterns 115a, 115b, and 115c. Next, the remaining first to third patterns are removed.

According to the second embodiment, an interval between the first and the second hard mask patterns 115a and 115b, an interval between the second and the third hard mask patterns 115b and 115c, and the width of each of the first to third hard mask patterns 115a, 115b, and 115c are determined by the deposition thickness of the second auxiliary layer and the patterning process of the first auxiliary layer for forming the first to fourth trenches in the first auxiliary layer. The first to fourth trenches may be formed regardless of an alignment error of the exposure masks. According to the second embodiment, in forming an interval between the first and the second hard mask patterns 115a and 115b, an interval between the second and the third hard mask patterns 115b and 115c, and the width of each of the first to third hard mask patterns 115a and 115b, and 115c, errors may be prevented from occurring due to an alignment error of the exposure masks.

The word lines WL, the dummy word line PWL, and the select line DSL/SSL of FIG. 3 may be formed by pattering the structures 109, 107, and 105 using the first to third hard mask patterns 115a, 115b, and 115c as an etch mask.

As described above, as in the first embodiment, in the second embodiment, the interval between the select line and the word line may be controlled by the widths and intervals of the first to fourth trenches and the deposition thickness of a deposition layer (that is, the second auxiliary layer). Consequently, the interval between the select line and the word line may be prevented from being changed from a design value due to an alignment error of different exposure masks.

Furthermore, in the second embodiment, an interval between the first hard mask patterns, an interval between the first and the second hard mask patterns, and an interval between the second and the third hard mask pattern may be made identical with each other by controlling the widths and intervals of the first to fourth trenches and the thickness of the deposition layer. In this case, the etch rate may become uniform when the exposed regions of the stack layers are etched because the width of each of the stack layers exposed between the first hard mask patterns, between the first and the second hard mask patterns, and between the second and the third hard mask patterns may become uniform. Consequently, damage to the gate insulating layer and the active regions, generated because the etch rate becomes irregular owing to a difference in the width of the region exposed through the hard mask pattern, may be prevented from being caused.

Furthermore, in the second embodiment, the width of the dummy word line formed to prevent an occurrence of disturbance may be controlled to have a desired width by controlling the interval between the first and the second trenches.

As described above, the patterns for defining the regions where the gate lines will be formed are self-aligned. An interval between the patterns for defining the regions where the gate lines will be formed is determined by the photolithography process employing one exposure mask and the thickness of the deposition layer. Accordingly, the interval between the gate lines may be prevented from being changed from a design value owing to an alignment error of different exposure masks.

Furthermore, since an error value of the interval between the word line and the select line is reduced, the distance between the select line and the word line may become uniform. When the distance between the select line and the word line becomes uniform, a disturbance may be prevented from occurring in memory cells coupled to word lines adjacent to the select line.

What is claimed is:

1. A method of forming patterns of a semiconductor device, comprising:
forming a hard mask layer over stack layers including first to third regions;
forming first patterns on the hard mask layer of the first region and second and third patterns, including first auxiliary layer and spacers formed on both sides of the first auxiliary layer, on the hard mask layer of the second and the third regions;
forming hard mask patterns by etching the hard mask layer exposed through the first to third patterns; and
forming word lines in the first region, a dummy word line in the second region, and select lines in the third region by etching the stack layers exposed through the hard mask patterns.

2. The method of claim 1, wherein the forming of the first patterns comprises:
forming the first auxiliary layer on an entire surface of the hard mask layer;
forming first to fourth trenches by etching the first auxiliary layer, wherein the first trenches are disposed in the first region, the second trench is disposed at a boundary of the first and the second regions, the third trench is disposed at a boundary of the second and the third regions, and the fourth trenches are disposed in the third region;
forming a second auxiliary layer along an entire surface including the first to fourth trenches;
performing a first etch process of the second auxiliary layer, wherein the second auxiliary layer of the first region remains on sidewalls of the first trenches and on a sidewall of the second trench close to the first region as the first patterns; and
removing the first auxiliary layer of the first region.

3. The method of claim 2, wherein the performing of the first etch process comprises:
forming a third auxiliary layer on an entire surface of the second auxiliary layer to fill the first to fourth trenches;
forming a protection pattern covering the second and the third regions and a part of a region of the second trench on the third auxiliary layer;
exposing the second auxiliary layer of the first region by etching exposed regions of the third auxiliary layer by using the protection pattern as an etch mask;
etching the exposed regions of the second auxiliary layer by an etch-back method to expose top surfaces of the first auxiliary layers and the hard mask layer in the first region; and
removing the protection pattern and the third auxiliary layer.

4. The method of claim 3, wherein the protection pattern is formed of photoresist material.

5. The method of claim 3, wherein the third auxiliary layer is formed of a spin on carbon (SOC) layer or a bottom anti-reflection coating (BARC) layer.

6. The method of claim 2, wherein the forming of the second and the third patterns comprises forming the spacers on the other sidewall of the second trench close to the second region and on sidewalls of the third and the fourth trenches by performing a second etch process of etching the second auxiliary layer in the second and the third regions by an etch-back method, after the first etch process of the second auxiliary layer,
wherein the hard mask layer is exposed in the second and the third regions.

7. The method of claim 2, wherein a width of the first trench is three times an interval between the first trenches.

8. The method of claim 2, wherein an interval between the first and the second trenches is identical with an interval between the first trenches.

9. The method of claim 2, wherein a width of the second trench is identical with a width of the first trench.

10. The method of claim 2, wherein a width of the fourth trench is greater than a width of the first trench.

11. The method of claim 2, wherein an interval between the second and the third trenches is equal to or greater than an interval between the first trenches.

12. The method of claim 1, wherein the forming of the first patterns comprises:
forming the first auxiliary layer on an entire surface of the hard mask layer;
forming first to fourth trenches by etching the first auxiliary layer, wherein the first trenches are disposed in the first region, the second trench is disposed at a boundary of the first and the second regions, the third trench is disposed at a boundary of the second and the third regions, and the fourth trenches are disposed in the third region;
forming a second auxiliary layer along an entire surface including the first to fourth trenches and forming a third auxiliary layer, covering the second and the third regions, on the second auxiliary layer;
etching the second auxiliary layer, wherein the second auxiliary layer remains on sidewalls of the first trenches as the first patterns and then removing the first auxiliary layer of the first region exposed through the etched second auxiliary layer;
etching the third auxiliary layer, wherein the second auxiliary layer between the first and the second trenches, between the second and the third trenches, and between the third and the fourth trenches is exposed;
etching the exposed regions of the second auxiliary layer, wherein the second auxiliary layers remains on a sidewall of the second trench close to the first region remain as the first patterns; and
removing the first auxiliary layer remaining in the first region.

13. The method of claim 12, wherein the forming of the third auxiliary layer comprises:
forming the third auxiliary layer on the second auxiliary layer to fill the first to fourth trenches;
forming a fourth auxiliary layer on the third auxiliary layer;
forming a protection pattern, covering the second and the third regions and ending in a region of the first auxiliary layer between the first and the second trenches or a region of the second trench, on the fourth auxiliary layer; and
etching the fourth and third auxiliary layers exposed through the protection pattern.

14. The method of claim 13, further comprising removing the protection pattern and the remaining fourth auxiliary layer, before exposing the second auxiliary layer between the first and the second trenches, between the second and the third trenches, and between the third and the fourth trenches.

15. The method of claim 13, wherein:
the protection pattern is formed of photoresist material;
the fourth auxiliary layer is formed of an SiON layer; and
the third auxiliary layer is formed of a spin on carbon (SOC) layer or a bottom anti-reflection coating (BARC) layer.

16. The method of claim 12, wherein the forming of the second and the third patterns comprises forming the spacers on the other sidewall of the second trench close to the second region and on sidewalls of the third and the fourth trenches by etching the second auxiliary layer in the second and the third regions by an etch-back method, after the removing of the first auxiliary layer,
wherein the hard mask layer is exposed in the second and the third regions.

17. The method of claim 12, wherein a width of the first trench is three times an interval between the first trenches.

18. The method of claim 12, wherein an interval between the first and the second trenches is identical with an interval between the first trenches.

19. The method of claim 12, wherein a width of the second trench is identical with a width of the first trench.

20. The method of claim 12, wherein a width of the fourth trench is greater than a width of the first trench.

21. The method of claim 1, wherein an interval between the second and the third trenches is equal to or greater than an interval between the first trenches.

22. The method of claim 1, wherein the stack layers comprise:
a gate insulating layer formed over a semiconductor substrate;
a first conductive layer;
a dielectric layer including a contact hole in the third region; and
a second conductive layer electrically coupled to the first conductive layer through the contact hole.

23. A method of forming patterns of a semiconductor device, comprising:
forming a hard mask layer over stack layers including first to third regions;
forming a first auxiliary layer over the hard mask layer and forming first to fourth trenches by etching the first auxiliary layer, wherein the first trenches are disposed in the first region, the second trench is disposed at a boundary of the first region and the second region, the third trench is disposed at a boundary of the second region and the third region, and the fourth trench is disposed in the third region;
forming a second auxiliary layer along an entire surface including the first to fourth trenches and forming first spacers on sidewalls of the first trenches and on a sidewall of the second trench close to the first region by etching the second auxiliary layer in the first region;
removing the first auxiliary layer in the first region and then forming second spacers on the other sidewall of the second trench close to the second region and on sidewalls of the third and the fourth trenches by etching the second auxiliary layer in the second and third regions;
forming hard mask patterns by etching the hard mask layer exposed between the first and the second spacers and the remaining first auxiliary layer; and
forming word lines in the first region, a dummy word line in the second region, and a select line in the third region by etching the stack layers exposed through the hard mask patterns.

24. The method of claim 23, wherein a width of the first trench is three times an interval between the first trenches.

25. The method of claim 23, wherein an interval between the first and the second trenches is identical with an interval between the first trenches.

26. The method of claim 23, wherein a width of the second trench is identical with a width of the first trench.

27. The method of claim 23, wherein a width of the fourth trench is greater than a width of the first trench.

28. The method of claim 23, wherein an interval between the second and the third trenches is equal to or greater than an interval between the first trenches.

29. The method of claim 23, wherein the forming of the first spacers comprises:
forming a third auxiliary layer on an entire surface of the second auxiliary layer to fill the first to fourth trenches;
forming a protection pattern covering the second and the third regions and a part of a region of the second trench on the third auxiliary layer;
exposing the second auxiliary layer of the first region by etching exposed regions of the third auxiliary layer by using the protection pattern as an etch mask;
etching the exposed regions of the second auxiliary layer to expose top surfaces of the first auxiliary layers and the hard mask layer in the first region; and
removing the protection pattern and the third auxiliary layer.

30. The method of claim 29, wherein the protection pattern is formed of photoresist material.

31. The method of claim 29, wherein the third auxiliary layer is formed of a spin on carbon (SOC) layer or a bottom anti-reflection coating (BARC) layer.

32. The method of claim 23, wherein the stack layers comprise:
a gate insulating layer formed over a semiconductor substrate;
a first conductive layer;
a dielectric layer including a contact hole in the third region; and
a second conductive layer electrically coupled to the first conductive layer through the contact hole.

33. A method of forming patterns of a semiconductor device, comprising:
forming a hard mask layer over stack layers including first to third regions;
forming a first auxiliary layer over the hard mask layer and forming first to fourth trenches by etching the first auxiliary layer, wherein the first trenches are disposed in the first region, the second trench is disposed at a boundary of the first region and the second region, the third trench is disposed at a boundary of the second region and the third region, and the fourth trench is disposed in the third region;
forming a second auxiliary layer along an entire surface including the first to fourth trenches and forming a third auxiliary layer, covering the second and the third regions, on the second auxiliary layer;
forming first spacers in the first region by etching the second auxiliary layer exposed through the third auxiliary layer, wherein a top surface of the first auxiliary layer between the first trenches is exposed;
removing the exposed regions of the first auxiliary layer and then forming second spacers on sidewalls of the second to fourth trenches by etching the third auxiliary layer and the second auxiliary layer, wherein the first auxiliary layer between the first and the second trenches, between the second and the first trenches, and between the third and the fourth trenches is exposed and the hard mask layer is exposed through bottom surfaces of the second to fourth trenches;
forming hard mask patterns by etching the hard mask layer exposed between the first and the second spacers and the remaining first auxiliary layer; and
forming word lines in the first region, a dummy word line in the second region, and a select line in the third region by exposing the stack layers exposed through the hard mask patterns.

34. The method of claim 33, wherein a width of the first trench is three times an interval between the first trenches.

35. The method of claim 33, wherein an interval between the first and the second trenches is identical with an interval between the first trenches.

36. The method of claim 33, wherein a width of the second trench is identical with a width of the first trench.

37. The method of claim 33, wherein a width of the fourth trench is greater than a width of the first trench.

38. The method of claim 33, wherein an interval between the second and the third trenches is equal to or greater than an interval between the first trenches.

39. The method of claim 33, wherein the forming of the third auxiliary layer comprises:
forming the third auxiliary layer on the second auxiliary layer to fill the first to fourth trenches;
forming a fourth auxiliary layer on the third auxiliary layer;
forming a protection pattern, covering the second and the third regions and ending in a region of the first auxiliary layer between the first and the second trenches or a region of a bottom surface of the second trench, on the fourth auxiliary layer; and
etching the fourth and third auxiliary layers exposed through the protection pattern.

40. The method of claim 39, further comprising removing the protection pattern and the remaining fourth auxiliary layer, before the forming of the second spacers.

41. The method of claim 39, wherein:
the protection pattern is formed of photoresist material;
the fourth auxiliary layer is formed of an SiON layer; and
the third auxiliary layer is formed of a spin on carbon (SOC) layer or a bottom anti-reflection coating (BARC) layer.

42. The method of claim 33, wherein the stack layers comprise:
a gate insulating layer formed over a semiconductor substrate;
a first conductive layer;
a dielectric layer including a contact hole in the third region; and
a second conductive layer electrically coupled to the first conductive layer through the contact hole.
